(19) United States
(12) Patent Application Publication
(10) Pub. No.: US 2006/0057388 A1
(43) Pub. Date: Mar. 16, 2006

(54) Aligned and open-ended nanotube structure and method for making the same

(76) Inventors: Sungho Jin, San Diego, CA (US); Dong-Wook Kim, San Diego, CA (US); In Kyung Yoo, Kyongki-do (KR)

Correspondence Address: HARNESS, DICKEY & PIERCE, P.L.C., P.O. BOX 8910, RESTON, VA, 20195, US

(21) Appl. No.: 11/223,136

(22) Filed: Sep. 12, 2005

Related U.S. Application Data
(60) Provisional application No. 60/608,641, filed on Sep. 10, 2004.

(51) Int. Cl. C23C 14/00; B32B 9/00

(52) U.S. Cl. 428/408; 204/192.15; 204/192.32

(57) ABSTRACT

Aligned and open-ended nanotube structures, methods for making the same, and devices including open-ended nanotubes. An aligned and open-ended nanotube structure which is free of catalyst particles at top ends, the aligned and open-ended nanotube structure having an uneven open-end height with local protruding portions. A method of opening an end of a nanotube including a catalyst particle including sputter etching the nanotube to remove an amorphous layer, bend the nanotube to one side, open a hole in the nanotube, and cause detachment of the catalyst particle.

### PRIORITY STATEMENT

This application claims the benefit of U.S. Provisional Patent Application No. 60/608,641, filed on Sep. 10, 2004, in the U.S. Patent and Trademark Office, the disclosure of which is incorporated herein in its entirety by reference.

### BACKGROUND OF THE INVENTION

1. Field of the Invention

Example embodiments of the present invention relate to aligned and open-ended nanotube structures, methods for making the same, and devices including open-ended nanotubes, for example, carbon nanotubes with vertically aligned structure and devices including open-ended nanotubes with vertically aligned structure.

2. Description of the Related Art

Carbon nanotubes (CNTs) have been studied for many different applications due to their electrical and/or mechanical properties. Carbon nanotubes have already been shown to be useful for a variety of applications, for example, field emission devices, nanoscale electromechanical actuators, field-effect transistors (FETs), CNT based random access memory (RAM), and atomic force microscope (AFM) probes.

The ends of CNTs, as synthesized, may be capped by a hemispherical carbon structure of various forms or by a catalyst particle and several methods of opening the ends of carbon nanotubes have been demonstrated.

FIG. 1A illustrates a cross-sectional configuration of conventional art nanotubes with a vertically aligned structure with the nanotubes having catalyst particles at the upper ends. Because of the catalyst particles, the nanotube core may not be accessible for additional fabrication, for example, core filling. Also, the rounded tip of the catalyst particles may provide a somewhat larger radius of curvature, which may diminish the field concentration effect during field emission under an applied electric field.

Heating CNTs in the presence of air for short durations at temperatures at about 700° C. may result in the burning away of the tube caps and/or the thinning of tube walls. However, opening all of the tubes may require oxidizing the majority of the CNTs.

Acid solutions, for example, solutions of hydrochloric acid, also have been shown to chemically etch and remove catalyst particles, leaving open CNT ends.

Cutting CNTs leaving open ends on both cut ends has also been demonstrated using acid solutions, for example, nitric acid, supercritical water, ball milling, diamond particle abrasive, and dynamic nano-fragmententation.

Open ends of CNTs from the bottom of detached nanotubes from the substrate have been shown to exhibit improved field emission at lower fields than capped CNTs. Intentional opening of the top ends of aligned CNTs has been demonstrated by introducing CO₂ into the same CVD chamber that CNTs were grown to oxidize the caps. Opened aligned CNTs may also be achieved by H₂O plasma etching followed by hydrochloric acid etching.

These various, conventional methods are based primarily on three principles, namely, i) wet chemical dissolution, ii) mechanical break-up, or iii) high temperature oxygen-assisted burning. However, CNTs opened via these methods may be of disparate lengths, may have their vertical alignment configuration disrupted, e.g., by their bundling during wet processing, and/or may have their walls damaged and/or their surfaces functionalized by strong acids.

### SUMMARY OF THE INVENTION

Example embodiments of the present invention are directed to methods of near room-temperature nanotube end-opening using sputter etching process and/or neck severing below the catalyst particles in a plasma.

Example embodiments of the present invention are directed to methods of near room-temperature nanotube end-opening without wet processing or a high temperature oxidation process.

Example embodiments of the present invention are directed to methods wherein the sputter etching is carried out with hydrogen ions or argon ions.

Example embodiments of the present invention are directed to methods wherein the nanotube is carbon nanotube in a vertically parallel aligned array configuration.

Example embodiments of the present invention are directed to methods wherein the nanotubes with catalyst particles are in a gated cell structure.

Example embodiments of the present invention are directed to catalyst-free or substantially catalyst-free, open-ended nanotube structures with vertical alignment prepared by any of the above methods.

Example embodiments of the present invention are directed to open-ended nanotube structures or articles including aligned and/or open-ended nanotube structures which are free or substantially free of catalyst particles at the top ends.

Example embodiments of the present invention are directed to open-ended nanotube structures or articles including aligned and/or open-ended nanotube structures with an uneven open-end height with local protruding portions and the average unevenness being at least 2 nm, or at least 10 nm.

Example embodiments of the present invention are directed to open-ended nanotube structures or articles including aligned and/or open-ended nanotube structures with nanotube length at least 1 nm shorter or at least 5 nm shorter than the nanotubes before the sputter etch end-opening.

Example embodiments of the present invention are directed to methods of creating open-ended nanotube array structures completely or partially metallic-bonded on a separate surface by optionally cleaning the upper surface of catalyst particles attached on the tip of vertically aligned carbon nanotubes by plasma etching, optionally depositing solderable or brazeable metals or solder alloys, such as Au, Ag, Cu, Sn, their alloys or solder alloys such as eutectic alloys, including Sn—Ag, Au—Sn, Sn—Sb, Sn—Cu, Bi—Sn or Pb—Sn, on the top surface of catalyst particles by physical or chemical deposition technique, for example, using oblique-incident sputtering or evaporation deposition, turning the solderable or brazeable nanotube array upside down and make a stronger and completely metallic or partially metallic bond on a new, possibly conductive substrate, such as, doped Si or other semiconductors, conductive ceramics, metal or metal coated substrates, and/or detaching the original substrate from the bonded assembly thus creating open-ended nanotube array.

Example embodiments of the present invention are directed to methods of creating open-ended nanotube array structures, wherein the solderable metals or solder alloys are applied as a thick layer, detaching this layer, flip it upside down, and solder bonding onto a conductive substrate.

Example embodiments of the present invention are directed to articles including vertically aligned and/or open-ended nanotube microstructures which are free or substantially free of catalyst particles at the top ends, and have catalyst metal particles at the bottom of nanotubes near the substrate metallically bonded to a substrate below with solder or braze.

Example embodiments of the present invention are directed to articles including vertically aligned and/or open-ended nanotube microstructures, wherein the metallic bond is solder or braze selected from Au, Ag, Cu, Sn, their alloys or solder alloys such as eutectic alloys, including Sn—Ag, Au—Sn, Sn—Sb, Sn—Cu, Bi—Sn or Pb—Sn.

Example embodiments of the present invention are directed to articles including vertically aligned and/or open-ended nanotube microstructures, wherein the article includes a field emitter device.

Example embodiments of the present invention are directed to articles including vertically aligned and/or open-ended nanotube microstructures, wherein the article is a microwave amplifier field emitter device.

Example embodiments of the present invention are directed to articles including vertically aligned and/or open-ended nanotube microstructures, wherein the article is a field emission display device.

Example embodiments of the present invention are directed to articles including vertically aligned and/or open-ended nanotube microstructures, wherein the article is a field emitter device based electron beam lithography nanofabrication tool.

Example embodiments of the present invention are directed to articles including vertically aligned and/or open-ended nanotube microstructures, wherein the article is a nano-needle array for delivery of
drugs, DNAs, proteins, and/or enzymes.

Example embodiments of the present invention are directed to articles including vertically aligned and/or open-ended nanotube microstructures, wherein the article is a nano-needle array for delivery of chemical reactants or catalysts for reactions, a lab-on-a-bench device, or a microfluidic device.

Example embodiments of the present invention are directed to articles including vertically aligned and/or open-ended nanotube microstructures, wherein the article is a hydrogen storage device.

Example embodiments of the present invention are directed to articles including vertically aligned and/or open-ended nanotube microstructures, wherein the article is a fuel cell.

Example embodiments of the present invention are directed to methods of nanotube end-opening which avoid known deleterious effects on aligned CNTs.

In example embodiments of the present invention, carbon nanotubes (CNTs) may be grown in the form of well aligned, vertically oriented fibers on a substrate, either as a dense forest or as a patterned, spaced-apart array. Such a vertically aligned and straight nanotube geometry is useful for improved performance of electron field emitter designs.

If the normally capped top ends of carbon nanotubes geometrically aligned and fixed on a flat substrate can be made open, several advantages may result according to example embodiments of the present invention, for example, the field concentration at the open-end tip of the CNTs may be higher thus allowing electron field emission at a lower applied field than conventional capped nanotubes. Other advantages of example embodiments of the present invention include ease of fabricating nano-composite materials and structures by filling the now-accessible nanotube core with other materials, ease of fabricating and using such an open-ended nanotube array as a nano-needle delivery device for therapeutic drugs, biological, molecules such as DNA for gene therapy, enzymes and proteins to influence cell behavior in animals, humans or plants, nano-scale delivery of chemical reactants such as catalysts, etc.

Example embodiments of the present invention disclose open-ended nanotube structures in a vertically aligned configuration, which may be obtained using fabrication techniques according to other example embodiments of the present invention, such as a convenient, room temperature sputter etching process in-situ in the same nanotube growth chamber, or an equal-height nanotube transfer technique employing an added metallized solderable surface.

Example embodiments of the present invention for opening ends of nanotubes may have the advantages of avoiding any high temperature oxidation reactions, chemical acid etching, and/or mechanical break-up. High temperature processing can cause damages to device structures especially semiconductor circuits and components. Wet chemical processing such as acid etching of catalyst particles, tend to cause nanotube clumping due to exposure to the aqueous or other liquid environments. Mechanical breaking up of nanotubes to open the ends can not easily be used on vertically aligned nanotubes on a substrate (such as silicon substrate), and any attempt to control nanotube shape by mechanical means may also disrupt the nanotube alignment. Further advantages may appear more fully upon considering the detailed description of example embodiments provided below.

### BRIEF DESCRIPTION OF THE DRAWINGS

The present invention will become more apparent by describing in detail example embodiments thereof with reference to the attached drawings.

FIG. 1A illustrates a cross-sectional configuration of conventional vertically aligned nanotubes with catalyst particle present at the top.

FIG. 1B illustrates a cross-sectional configuration of an open-ended nanotube array according to an example embodiment of the present invention.

FIGS. 2A-2C show the sequential change of an example nanotube microstructure during a sputter etching process of end-opening according to an example embodiment of the present invention, as shown by a scanning electron microscopy (SEM). In particular, FIG. 2A illustrates the start of the sputter etching processing, FIG. 2B during the CNT opening process, and FIG. 2C after catalyst particles have been removed, leaving CNT open at their top ends.

FIGS. 3A-3B illustrate two top view SEM images for CNTs. In particular, FIG. 3A illustrates before plasma processing and FIG. 3B after catalyst particles have been removed leaving open CNTs.

FIGS. 4A-4E illustrate a mechanism for nanotube end-opening according to an example embodiment of the present invention. In particular, in FIG. 4A, the catalyst particle may be initially covered with an amorphous carbon layer, in FIG. 4B, the amorphous carbon layer may be removed by sputter etching, and in FIG. 4C, the catalyst particle is reduced in size and the CNT is bent to one side by further sputter etching. In FIG. 4D, parts of the CNT that are on the sides of the catalyst particle and on the upper part of the bent-over nanotubes are thinned and eventually sputtered away resulting in an opening and in FIG. 4E, eventually, the plasma processing causes the catalyst particle to completely detach from the CNT and get swept away when its remaining supporting carbon wall breaks off.

FIGS. 5A-5B illustrate forming nanotube end-openings in-situ, according to an example embodiment of the present invention,
and a direct sputter etch process, according to an example embodiment of the present invention, respectively, on field emitter nanotube array tips in a cathode structure having a spacer and gate array.

FIG. 6 illustrates a field emitter device including a cathode with open-ended nanotubes, a gate, an anode, and power supply according to an example embodiment of the present the invention.

FIGS. 7A-7D illustrate a process for obtaining an open-ended nanotube array on a flat substrate by optionally coating a catalyst metal particle with a solderable or braze-able metallic material followed by transfer bonding of nanotubes using a metallic interface according to an example embodiment of the present the invention.

FIGS. 8A-8F illustrate a process for obtaining an open-ended nanotube array by oblique incident deposition of layered, solderable or braze-able metallic material followed by transfer bonding of nanotubes using a metallic interface according to an example embodiment of the present the invention.

FIG. 9 illustrates an example microwave amplifier including a structural assembly according to an example embodiment of the present the invention.

FIG. 10 illustrates an example field emission display including a structural assembly according to an example embodiment of the present the invention.

FIG. 11 illustrates an example projection e-beam lithography apparatus with a cold cathode including a structural assembly according to an example embodiment of the present the invention.

FIG. 12 illustrates an example plasma display device including a structural assembly according to an example embodiment of the present invention for low voltage operation of the display.

FIGS. 13A-13C illustrate an example nano-needle array injector device according to an example embodiment of the present the invention.

FIG. 14 schematically illustrates an example hydrogen storage device according to an example embodiment of the present the invention.

It is to be understood that these drawings are for the purposes of illustrating the concepts of the invention and are not to scale. For example, the dimensions of some of the elements are exaggerated relative to each other.

### DETAILED DESCRIPTION OF EXAMPLE EMBODIMENTS OF THE PRESENT INVENTION

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

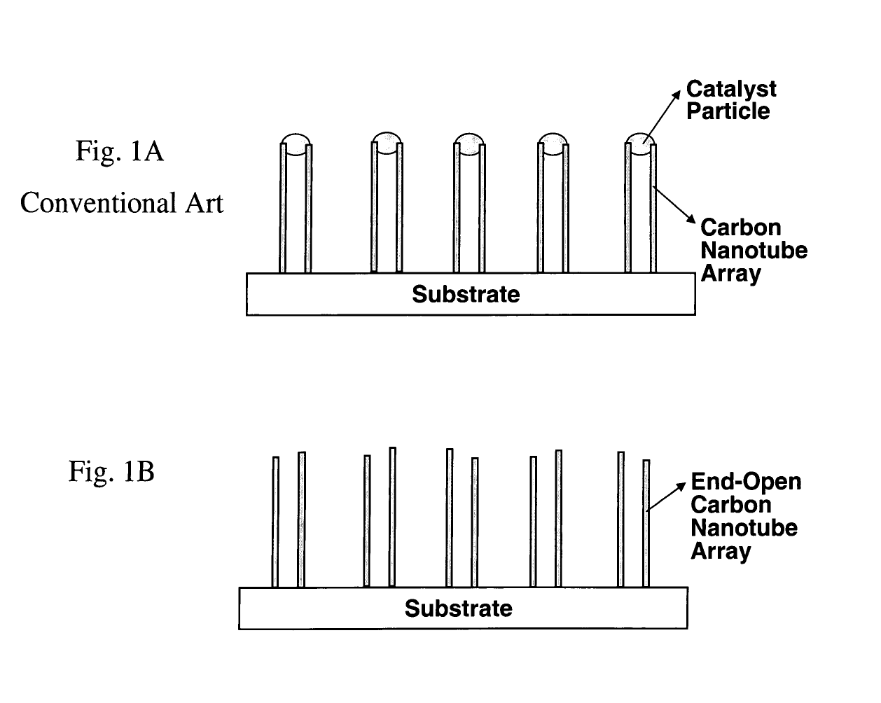

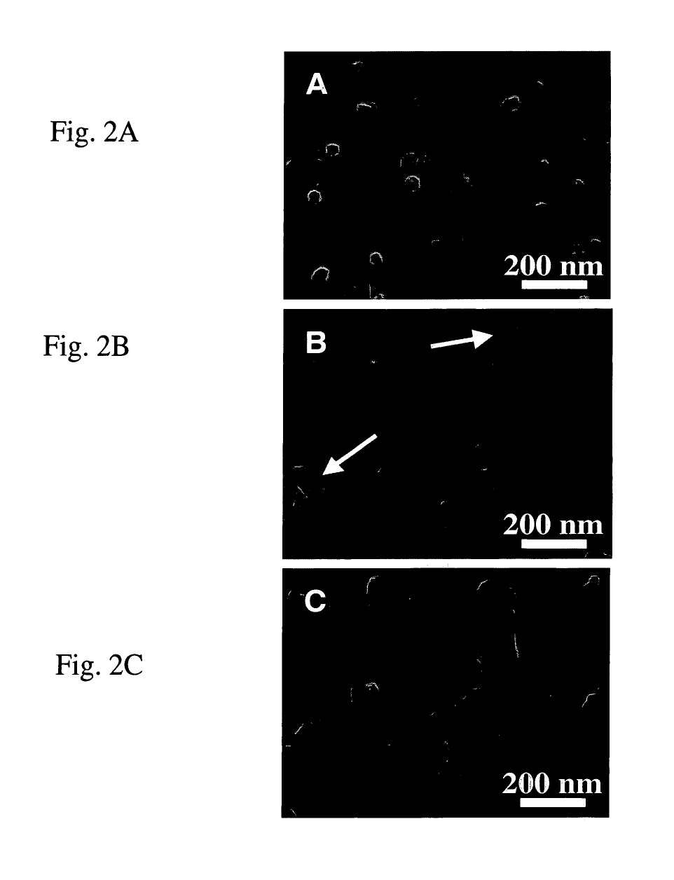

Referring to the drawings, FIG. 1B. illustrates an open-ended nanotube array according to an example embodiment of the present invention. Such a structure may be obtained by several different example approaches. One such example approach is a selected sputter etch process, example processing of which is described in more detail below.

An aligned array of CNT samples may first be prepared using a DC plasma-enhanced chemical vapor deposition (PECVD) process using Ni catalyst particles with a tip-growth mechanism. A mixed gas of ammonia (NH₃) and acetylene (C₂H₂) may be used for the CVD growth. An example array may have a density of approximately 2×10⁹ CNTs/cm². The example array may be fabricated by first sputter depositing a 50 Å thick Ni film over the surface of an n-type Si (100) substrate. The substrate may then be transferred (in air) to the CVD chamber. Upon heating to approximately 700° C. in a low pressure hydrogen atmosphere, the Ni film may break up into islands with average diameters of 30 to 40 nm. After catalyst island formation, the atmosphere may be changed to NH₃ flowing at 150 sccm, for example. A DC bias of 500V may be applied, for example, between an anode above the sample and a cathode below the sample.

Under the applied voltage, plasma may be formed and C₂H₂ gas may then be added to the chamber flowing at 50 sccm, for example with the total NH₃ and C₂H₂ pressure being held at 3 torr, for example.

Sputter etching may then be performed at room temperature in the same DC plasma CVD system after the CNT growth was completed and the chamber was cooled to room temperature. In order to track the microstructural evolution during the nanotube opening, the etching of samples was interrupted in stages, with the sample being removed and examined before replacing in the chamber for further processing. For microstructural analysis, scanning electron microscopy (SEM) was performed using a Phillips field emission SEM operated at 15 kV.

Samples were first placed under H₂ flowing at 35 sccm and held at 0.5 Torr within the CVD chamber. A bias of 500 V was applied and plasma formed with a current of 2 mA. Subsequent plasma processing stages may involve increasing the H₂ flow rate to 70 sccm, increasing chamber pressure to 1 Torr, and increasing the processing time. Cumulative sputter etching time for samples may be 45-60 minutes with the majority of the time spent under relatively mild plasma conditions to cause a more controlled and gradual evolution of morphology so that all of the CNT opening stages could be observed.

The etching may started with the sample and chamber at room-temperature (23° C.) and the temperature may be increased during hydrogen plasma processing slightly, for example, less than 5° C.

In addition to hydrogen ions, sputter etching may also be performed using a heavier ion, for example, Ar. The flow rates employed may be in the range of 20 to 65 sccm, with a pressure of 0.5 Torr. Plasma may be formed under applied biases ranging from 300 to 500 35 V.

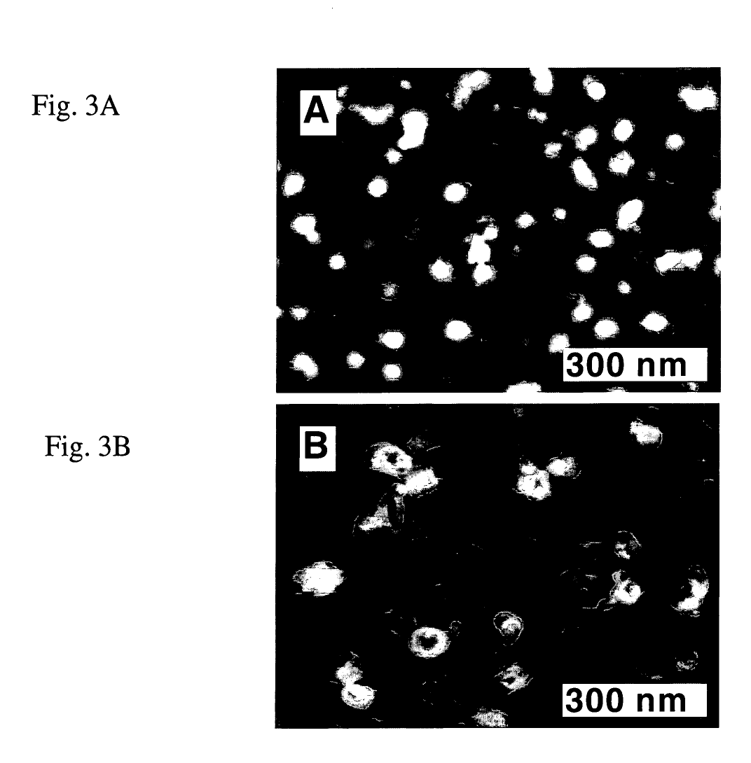

Multiple stages of plasma processing may be carried out to allow observation of the CNT opening process as it occurred so that the mechanism could be clearly understood. The images presented in FIGS. 2A-2C illustrate the evolution of microstructure at different stages of processing under H₂ plasma. FIG. 2A illustrates an aligned CNT forest-like array after being subjected to sputter etching under low pressure plasma for a short duration, for example, 60 seconds. The Ni catalyst particles are clearly visible as light balls at the tip of each CNT. After additional plasma processing, the walls of the CNTs just below the catalyst particles appear to be preferentially removed (see the arrows in FIG. 2B). Many of the catalyst particles are left hanging on by only remnants the CNT walls. Some of the catalyst particles have completely fallen off leaving open CNTs behind. The remaining catalyst particles appear to have reduced in size slightly.

After sufficient processing time, for example, approximately 30 minutes, most of the catalyst particles are completely detached. The detached particles, together with the remnant nanotube segments still attached to the particles, may be removed by a physical blast of gas flow in the chamber, leaving only open CNTs still aligned and attached to the substrate (shown in FIG. 2C).

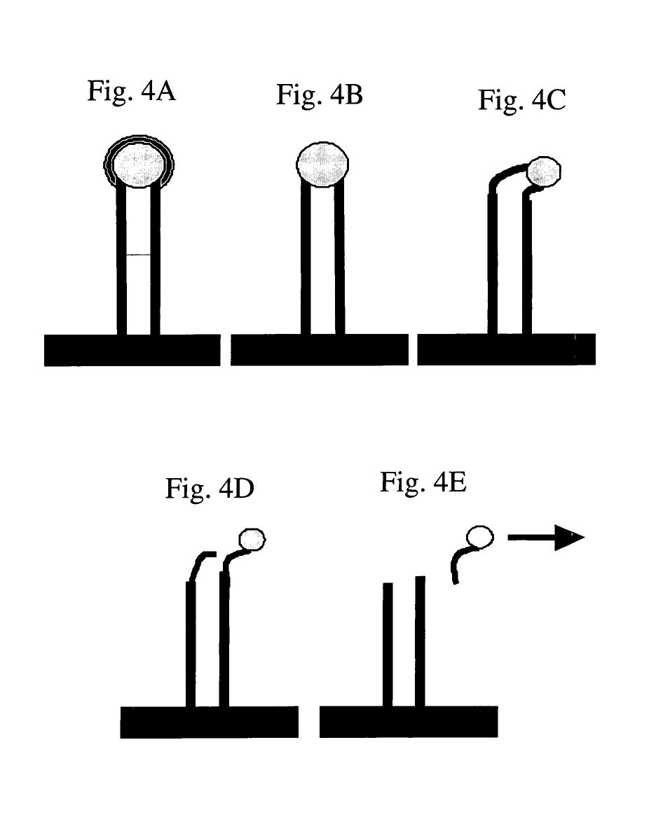

Additional SEM images of a sample before processing and after CNT opening are shown in FIGS. 3A and 3B. These example images were taken perpendicular to the sample surface, looking at the aligned CNTs along their growth direction. In FIG. 3A, the Ni catalyst particles are, as earlier, visible as bright, light balls. Also present in the as-grown aligned CNT array are additional small diameter CNTs that are not aligned and can be seen around and between the larger aligned CNTs. These smaller diameter CNTs may occur during the CVD growth of aligned CNTs, for example, when the CVD chamber is contaminated with carbon deposits near the electrodes and other parts after repeated CNT deposition.

Another benefit of the sputter etch process according to example embodiments of the present invention may be that these smaller diameter CNTs may also be preferentially etched away due to their orientations, allowing sputter etching to occur across most of their surfaces. An overall cleaner nanotube array structure may be obtained, as a result.

After the sputter etching process has removed all of the catalyst particles, it is easier to see the circular cross sections of the open CNTs shown in FIG. 3B. As shown, the smaller diameter CNTs that were present initially may also be completely sputtered away by the end of the hydrogen plasma etching processing.

According to other example embodiments of the present invention, the removal of the catalyst particles and opening of the CNTs may be caused by a localized, preferential sputter etching of selected locations in the nanotubes just below the catalyst particles, which may be followed by a “neck severing’ process.

In such an example embodiment of the present invention, the positive hydrogen ions in the plasma may be accelerated toward the substrate and collide with the CNTs. The presence of the plasma above the sample may create a plasma self-bias which adds to the bias applied between the anode and cathode stage used to form the plasma, as is well known. These two fields may act in the same direction and cause an acceleration of positive ions along the field lines until they terminate at the sample surface. The field lines above the sample may be perpendicular to the surface of the sample and the relatively small lengths of the CNTs may ensure that the incident ions move perpendicular to the substrate surface when they collide with the surface or with a CNT.

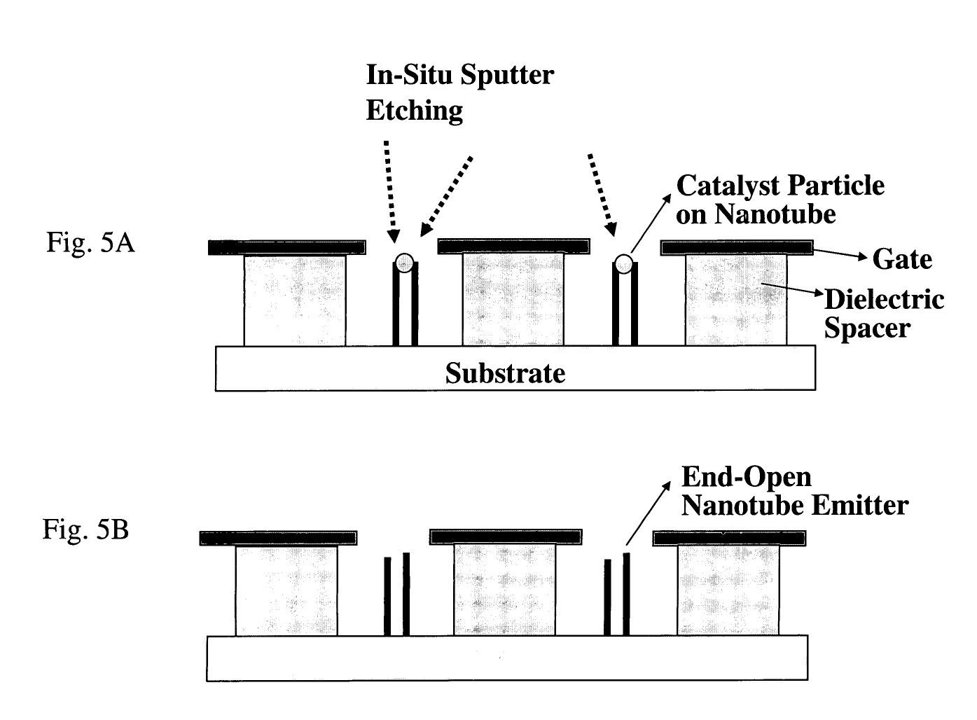

A schematic illustration of the mechanism for nanotube end opening according to an example embodiment of the present invention is shown in FIGS. 4A-4E as a sequence of events. Initially, a carbon nanotube may be vertically aligned with its catalyst particle at its tip. The catalyst particle may have a thin amorphous carbon coating on it after growth (as shown in FIG. 4A). Initial sputter etching may cause the removal of the amorphous carbon layer (as shown in FIG. 4B). Additional processing may cause the CNT to bend to one side (as shown in FIG. 4C). The direction of bending may appear to be random initially, but after the CNT begins to bend in one direction, further plasma processing may cause the CNT to continue to bend further in the same direction. In example embodiments, this may be due to defects and/or stresses caused by ion bombardment on one side of the CNT. Further, a lesser degree of sputtering of the catalyst particle may reduce its size.

As the sputter etching process continues, the walls of the CNT that have been bent over may be sputtered away. The parts of the CNT that have bent over provide a larger cross sectional area for the vertically descending ion bombardment of their surface which results in faster sputter etching. Eventually, the sputtering will lead to a hole forming in part of the bent over wall, and that opening will continue to grow (as shown in FIG. 4D).

After additional plasma processing, the portions of the CNT that had bent over are completely removed causing detachment of the catalyst particle and leaving behind an aligned and open CNT (as shown in FIG. 4E). The plasma gas flow may blow away the detached catalyst particles and small nanotube segments still attached to them.

According to example embodiments of the present invention, open-ended nanotubes may be uneven in terms of height, at the microstructural level. Due to predominantly directional sputter etching, an open-ended nanotube structure may not only be free of catalyst particles at the top ends, but also may have length variations (the height measured from the base of the nanotube), with some local protruding portions. Such a protrusion may be desirable as it may further enhance the field concentration and/or lower the threshold field needed for operation of field emission devices.

Such a protrusion may also be desirable for nano-needle array applications as the shape resembles that of a hypodermic needle and may be easier to inject into human or animal cells with reduced resistance to poking. The average deviation of the height in the nanotubes of a nanotube array according to example embodiments of the present invention may be at least 2 nm, and even at least 10 nm. The nanotubes of a nanotube array according to example embodiments of the present invention may also be shorter than before processing, with the average nanotube length being at least 1 nm shorter, and even at least 5 nm shorter than the nanotubes before the sputter etching the end openings.

Although an electric field may accelerate ions generally perpendicular to the substrate surface, individual ions may actually be moving in all directions due to the many collisions that may occur in a relatively high, pressure plasma. The distribution of ion directions may result in sputter etching occurring on all surfaces of the CNTs, but the electric field may result in a stronger preference for the incident hydrogen ions to be moving perpendicular to the surface when they collide with the surface or with a CNT. This tendency may result in preferential sputter etching from the top ends of the CNTs.

The removal of the amorphous carbon layer on the catalyst particle in the earlier stages of sputter etching may be useful in itself. For example, various objects, for example, other metal particles or biological molecules, may be attached to an exposed and clean catalyst metal particle through chemical or biological conjugations. Also, the cleaning of the catalyst particle surface may allow subsequent re-growth of carbon nanotubes after an initial growth stage has been stopped, as such a coating may be considered catalyst poisoning, which may be responsible for slowing down or terminating the continued growth of CNT by CVD processing. For successful growth of continuous or very long CNTs which may be desirable for some engineering applications, a removal of the carbon coating layer, for example, by hydrogen sputter etching according to example embodiments of the present invention may be beneficial.

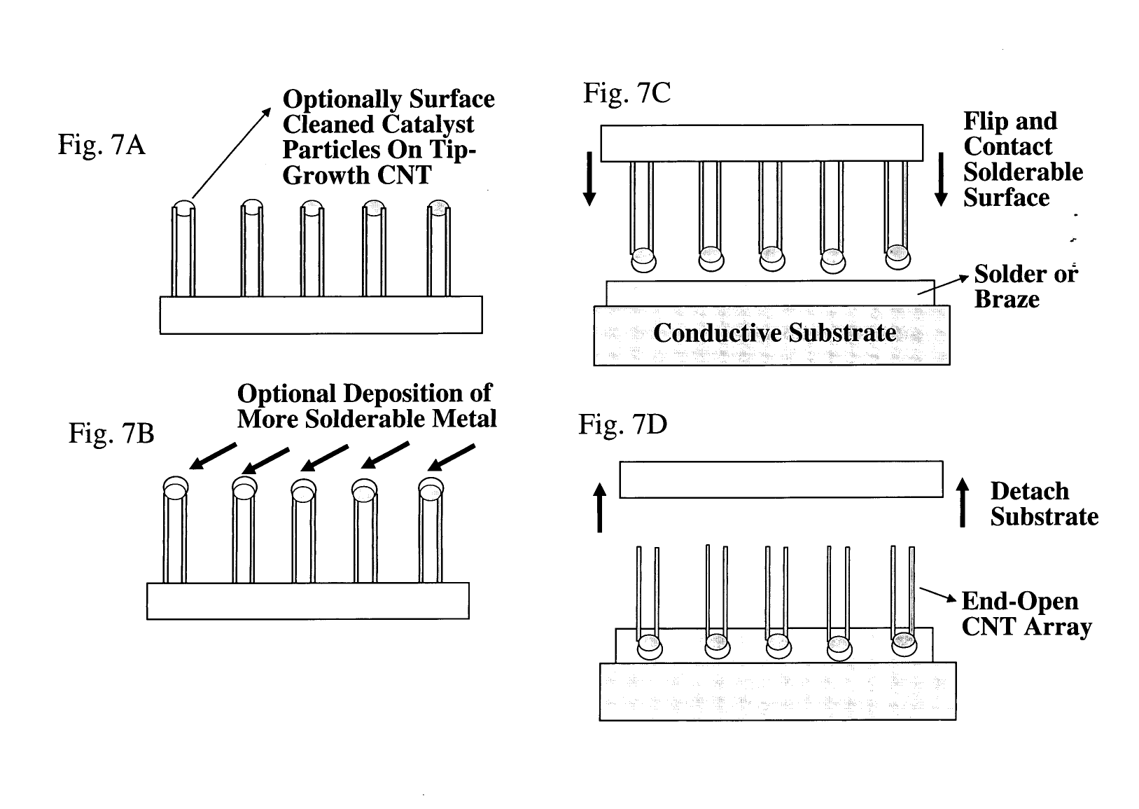

According to example embodiments of the present invention, removing the amorphous carbon layer from the surface of the catalyst metal particles (for example, Ni, Fe, Co or their alloys) may provide a now-clean surface, which may be a solderable (or easily brazeable) surface. Solderable ends of aligned nanotubes may be utilized to produce open-ended nanotubes by flip soldering on another, flat, conductive substrate followed by detaching the original Si substrate, as illustrated schematically in FIGS. 7A-7D below.

According to example embodiments of the present invention, similar end-opening of nanotubes by a neck severing mechanism using hydrogen ions may also be performed with other ions, for example, Ar ions in Ar plasma. According to example embodiments of the present invention, other gas species, for example, oxygen, nitrogen and/or ammonia may also be used for opening ends of vertically aligned carbon nanotubes.

Because the ions resulting from Ar plasma are much heavier than those resulting from a H₂ plasma, due to difference in molecular masses, a much stronger sputtering effect may occur, and as a result, a shorter etching time may be required to achieve, with Ar plasma, similar results as with H₂ plasma. With H₂ plasma, normally less than the top 100 nm length of a CNT may be removed, but with Ar plasma, an average of 250 nm may be removed from the top of each CNT. In general, hydrogen sputter etching process with lighter atoms may provide better control in nanotube end-opening.

The open-ended carbon nanotube array obtained by example embodiments of the present invention, may be based on a dry technique of in-situ sputter etching process. Because no wet processing, for example, acid etching used in conventional art nanotube end-opening need be employed, the end-opening may easily be applied to even a pre-assembled field emitter gate array device structure (for example, as shown in FIGS. 5A and 5B).

As shown in FIGS. 5A and 5B, an example device may include a substrate, a cathode, an insulating pillar layer (or dielectric spacer), a gate, and at least one vertically aligned carbon nanotube field emitter in each triode cell, which may be CVD grown after the fabrication of the basic gate structure using photolithography and/or electron-beam lithography process. These lithography processes may involve some wet processing, which may damage the alignment and integrity of the nanotubes if they were already present in the center of each cell. Therefore, it may be advantageous to grow the nanotubes (and to apply an in-situ nanotube end opening technique according to example embodiments of the present invention) after gate structure fabrication.

By applying an in-situ, sputter etch, nanotube end opening technique according to example embodiments of the present invention on the tip of nanotubes in the constructed gated device, as illustrated in FIG. 5B, an improved field emitter array structure with higher field concentration at the emitter tip may be obtained. In an example embodiment, this may be due to the overall sharp circular edges at the end of the open-ended nanotubes, which may provide a higher field amplification effect than a closed nanotube with either catalyst particles in the tip-growth CNTs or dome-shaped, catalyst-free ends in the base-growth CNTs.

As a result, a device including open ended nanotubes according to example embodiments of the present invention may advantageously be operated at a lower applied field. For example, an average applied electric field to obtain a similar level of field emission current in the field emitter structure of FIG. 5B according to an example embodiment of the present invention may be at least 20% lower, and may be at least 50% lower than in a conventional art device. The open ended nanotubes, according to example embodiments of the present invention, may be useful as more efficient field emitting tips in diode or triode field emitter devices.

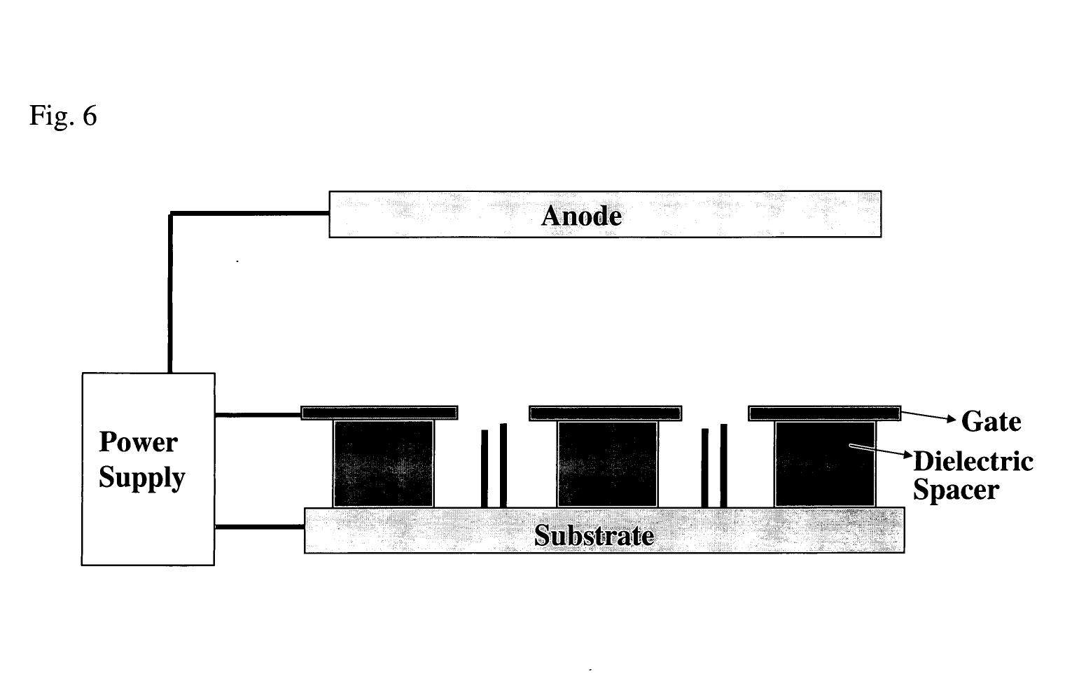

An example embodiment of a triode field emitter device including at least one open ended nanotube according to example embodiments of the present invention in each cell is illustrated in FIG. 6. A relatively small voltage applied to the gate may induce electrons to be extracted from the nanotube tip. These field emitted electrons may then be accelerated toward the anode to which a higher electric field is applied by the power supply.

In tip-growth type, aligned carbon nanotubes (or any other non-carbon nanotubes grown by a catalyst particle mediated synthesis process), the bottom part of the nanotubes, if detached from the substrate, may also provide open end tips, for example, as is known. However, in conventional processes, the CNT array is first removed (detached) from the substrate surface and re-mounted and/or bonded on a flat conductive surface using a conductive adhesive, for example, silver paste. Such a process may be cumbersome, may disrupt the nanotube array during handling (for example, through piling-up of razor-blade scraped nanotube clumps), may result in a weak, silver-paste, poorly conductive bonding of nanotubes on another substrate, and/or may be difficult to scale up for construction of industrially viable field emitter cathode structures.

Using in-situ preparation of an open ended CNT array via a neck-severing mechanism according to example embodiments of the present invention may be more convenient as the nanotubes are already attached on a conducting surface, vertical alignment of the nanotubes is not disturbed by the end-opening, and/or the nanotubes are more easily scaleable for large area emitter construction.

Another example embodiment of the present invention for opening the ends of carbon nanotubes may involve the use of the plucked-off bottom ends of nanotubes, without the sputter etch process, but with processing to reduce disruption of the vertically aligned nanotube geometry and/or provide stronger metallic bonding on transfer of the plucked-off nanotube array onto a new conductive substrate, as illustrated in FIGS. 7A-7D.

In an example embodiment of the present invention, as shown in FIG. 7A, vertically aligned, catalytically prepared nanotube array (for example a carbon nanotube, SiC nanotube, and/or various other types of nanotubes) may be prepared by DC, RF and/or microwave plasma CVD or simple thermal CVD processing. A surface of the catalyst particles, for example, Ni, if covered by amorphous carbon, may then be optionally plasma etch cleaned (e.g., by using hydrogen or Ar plasma). Under some nanotube CVD growth conditions, for example, if the time period of CVD growth is not overly long, the top surface of the catalyst metal particles may remain clean. In such a case, plasma surface cleaning may not be necessary and therefore, may be omitted.

As shown in FIG. 7B, the catalyst metal surface may be optionally coated with more solderable metal. While Ni itself is highly solderable and is often utilized in microelectronic packaging of Ni-coated contact pads, Co or Fe may be less solderable, and it may be advantageous if a more highly solderable coating was added on the metal particle surface for enhanced and/or more reliable solder or braze bonding. The more highly solderable coating material may be selected from metals, for example, Au, Ag, Cu, Sn, their alloys or solder alloys, or a eutectic alloy, for example, Sn—Ag, Au—Sn, Sn—Sb, Sn—Cu, Bi—Sn or Pb—Sn.

The solderable metals or alloys may be deposited on the catalyst particles by sputtering, evaporation and/or CVD processing. In an example embodiment, the deposition technique is oblique incident deposition by which the particles are preferentially coated with a reduced or minimal coating of the nanotube itself due to the shadowing effect. An alternative way of depositing solderable metals that can be utilized may include electroless or electrolytic deposition. The desired thickness of the solderable coating may be in the range of 0.1-100 nm, or in the range of 1-10 nm.

As shown in FIG. 7C, the nanotube array may be flipped over and brought into contact with another flat, optionally conductive substrate (for example, doped Si, a metallic substrate, for example, stainless steel, Cu, Pt, Ni) and solder- and/or braze-bonded. The new substrate may be pre-coated with a layer of solder and/or braze material or a thin layer of solder paste may be applied or pre-applied on the substrate surface. Solder bonding may take place by heating the assembly (or by preheating the substrate) to a temperature higher than the melting temperature of the solder material involved. For example, a bonding temperature of approximately 250° C. or higher can be used for a Sn-3.5% Ag eutectic solder (melting point approximately 221° C.) and approximately 300° C. or higher for Au-20% Sn eutectic solder (melting point approximately 278° C.). For brazing, braze alloys generally have higher melting temperatures, so a higher temperature, for example, 400-700° C., may be utilized.

As shown in FIG. 7D, the original substrate may be detached to expose the open ended nanotube tips. Due to stronger bonding of catalyst particles within the solder or braze, as compared with weaker bonding of a nanotube with Si substrate, nanotube detachment occurs relatively easily.

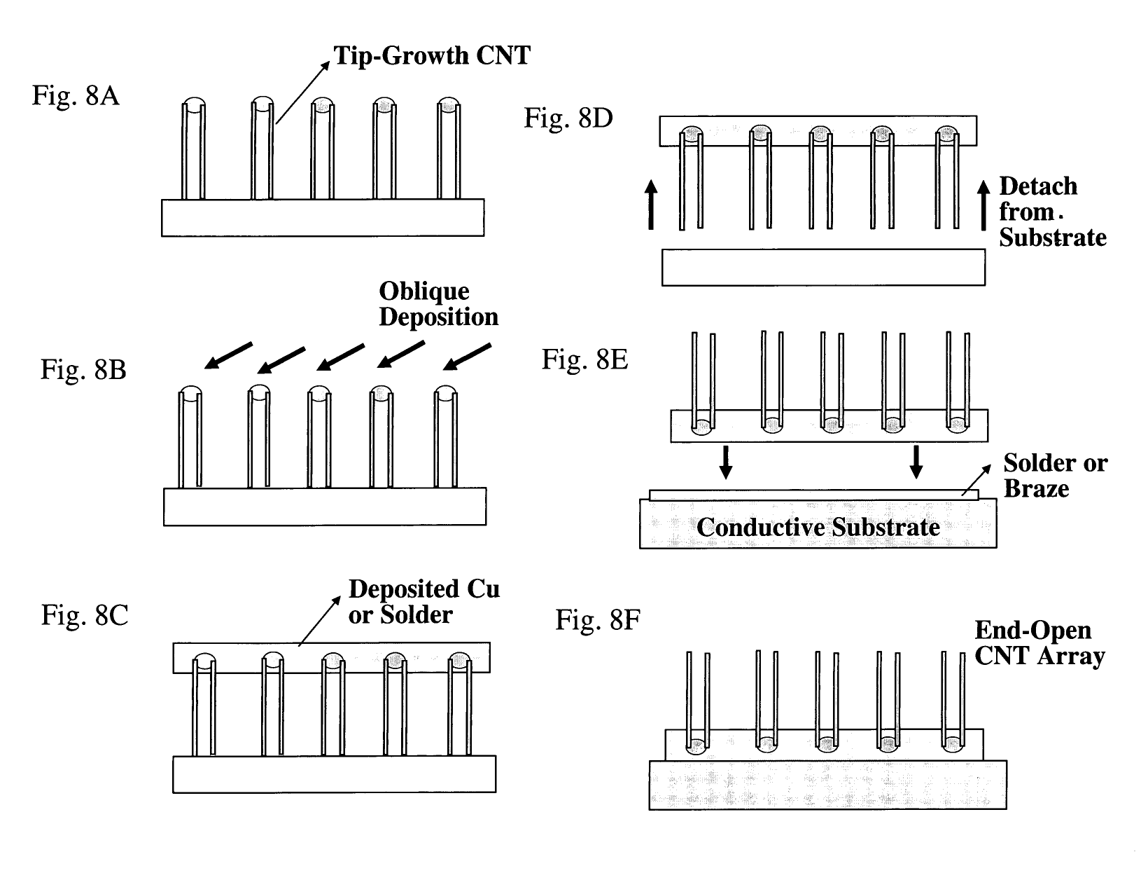

FIGS. 8A-8F illustrate constructing an open ended nanotube array by oblique incident deposition of layered solderable or brazeable metallic material followed by transfer bonding of nanotubes using a metallic interface in accordance another example embodiment of the present invention.

As shown in FIG. 8A, a vertically aligned nanotube array may be prepared, with an optional clean-up of amorphous carbon on the catalyst particle surface via plasma etch as discussed above with reference to FIGS. 7A-7D.

As shown in FIG. 8B, an oblique incident deposition of more solderable metal or solder material (for example, Au, Ag, Cu, Sn, their alloys or solder alloys such as eutectic alloys including, for example, Sn—Ag, Au—Sn, Sn—Sb, Sn—Cu, Bi—Sn or Pb—Sn) may be performed. The shadow effect of the vertically aligned nanotube configuration may allow a preferential deposition of the metal layer on the top area. A sufficiently long deposition time may be carried out so that a layer-like deposit is achieved, as shown in FIG. 8C. A desired layer thickness may be at least 50 nm, or at least 200 nm to increase the ease and/or reliability of handling the detached nanotube array during subsequent processing. As shown in FIG. 8D, the nanotube array may be detached from the substrate to expose the open ends of the nanotubes.

Optionally, a vacuum suction tool or magnetic holder (if the deposited metal layer includes a ferromagnetic material such as Ni, Fe, Co) may be utilized to more conveniently handle the detached nanotube array.

As shown in FIG. 8E, the detached nanotube array may be flipped over and the solderable layer may be contacted with another flat, optionally, conductive substrate (for example, doped Si, metallic substrate such as stainless steel, Cu, Pt, Ni) and solder- or braze-bonded. The new substrate may be pre-coated with a layer of solder or braze material or a thin layer of solder paste may be applied or pre-applied on the substrate surface.

As shown in FIG. 8E, the assembly may be heated (or the substrate is preheating) to a temperature higher than the melting temperature of the solder material involved. For example, a bonding temperature of approximately 250° C. or higher can be used for a Sn-3.5% Ag eutectic solder (melting point of approximately 221° C.) and approximately 300° C. or higher for Au-20% Sn eutectic solder (melting point of approximately 278° C.). For brazing, a higher temperature, for example, 400-700° C. may be used for melting and bonding.

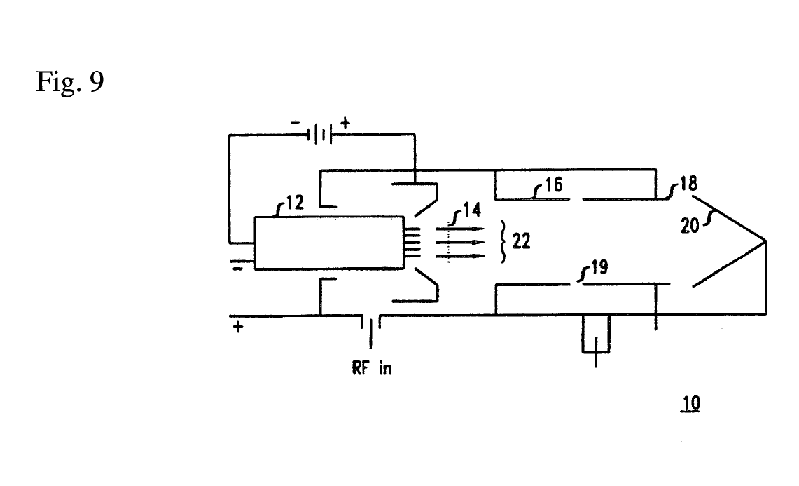

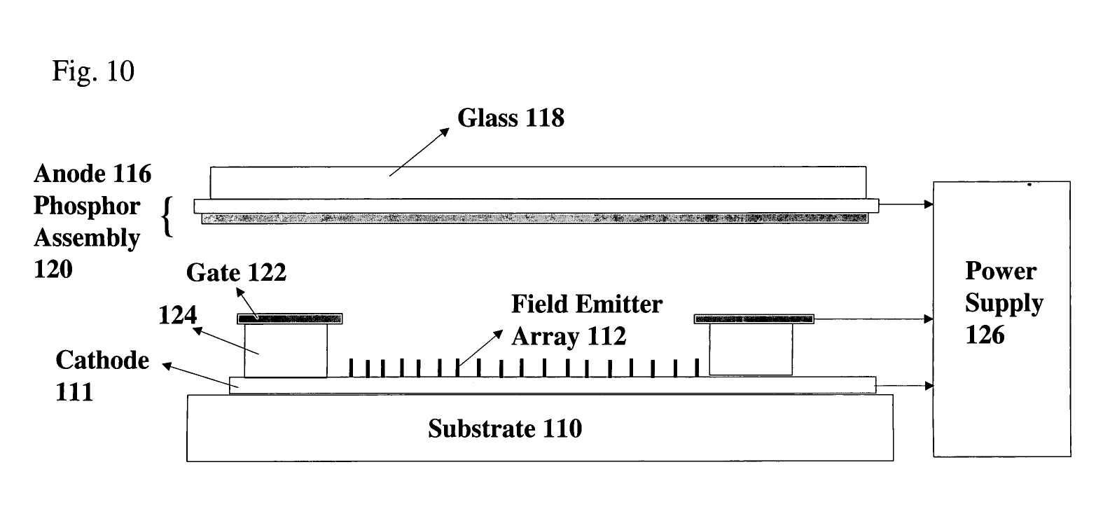

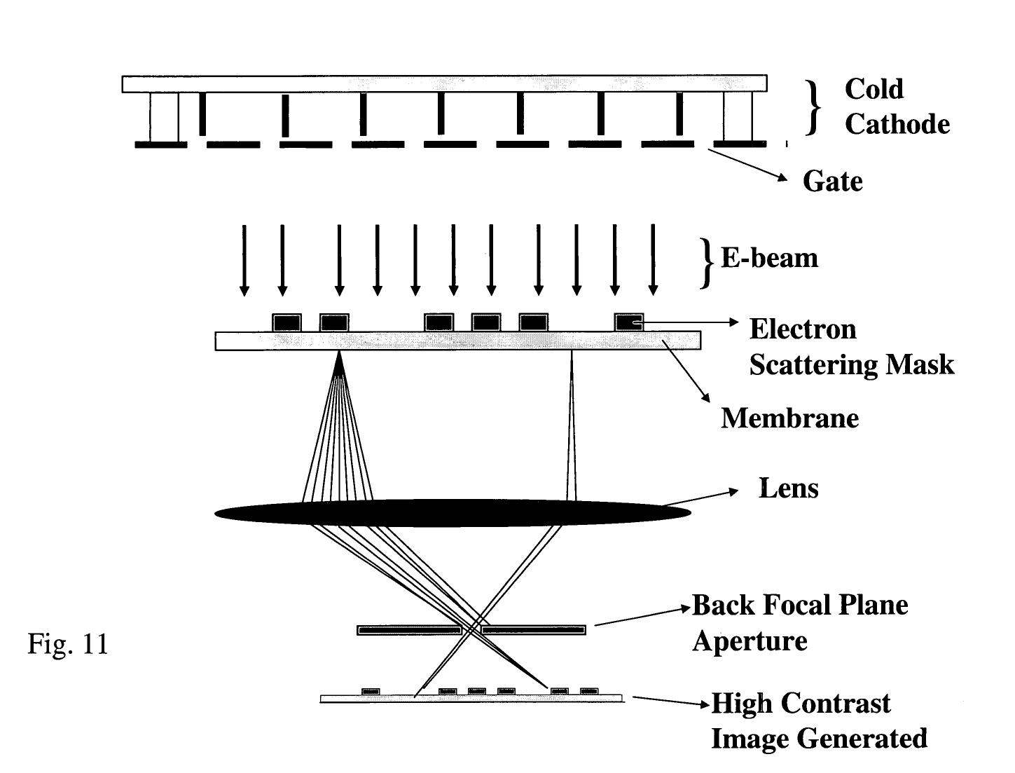

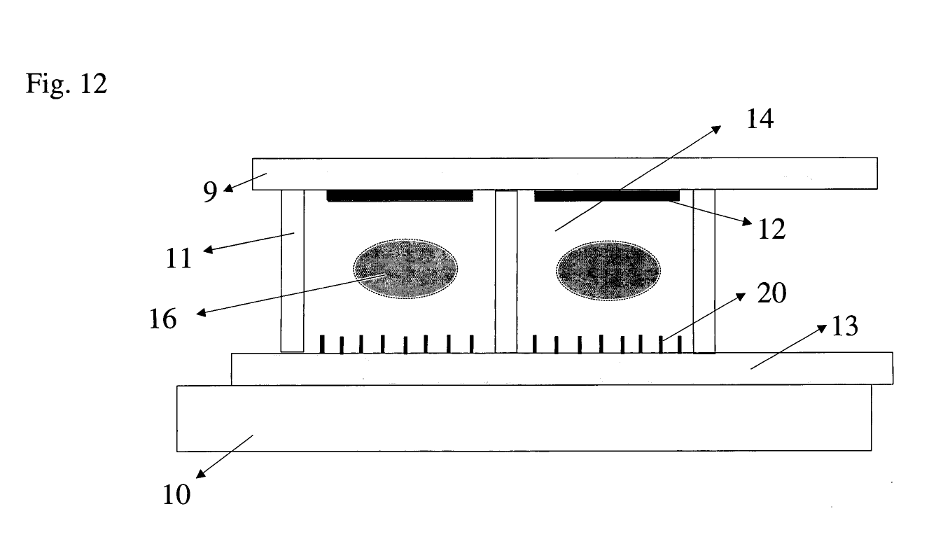

The open-ended nanotube arrays in accordance with example embodiments of the present invention may be advantageously utilized in various devices or processing tool applications. For example, nanotubes in accordance with example embodiments of the present invention (for example, with enhanced field concentrating capability) may be utilized as an improved field emission cathode for microwave amplifier device, as illustrated, for example, in FIG. 9, for field emission based, flat-panel displays as illustrated, for example, in FIG. 10, for a nano-fabrication electron-beam exposure source for electron projection lithography as illustrated, for example, in FIG. 11, and/or for plasma based flat-panel displays as illustrated, for example, in FIG. 12.

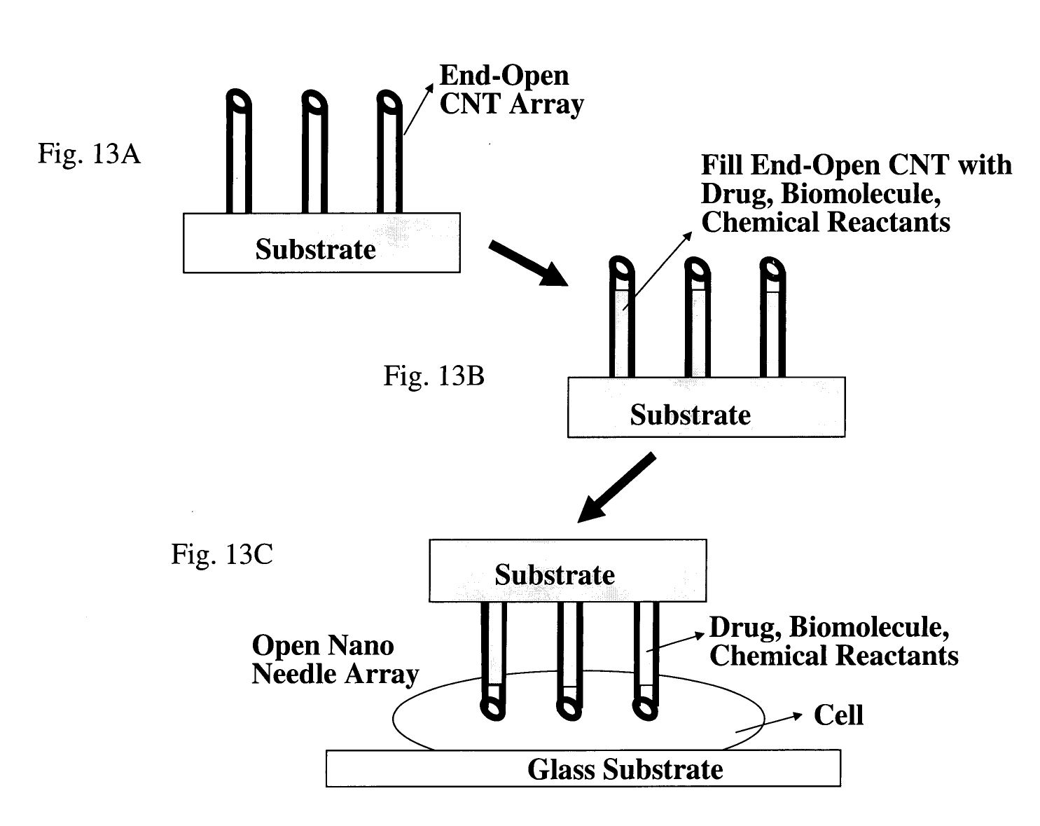

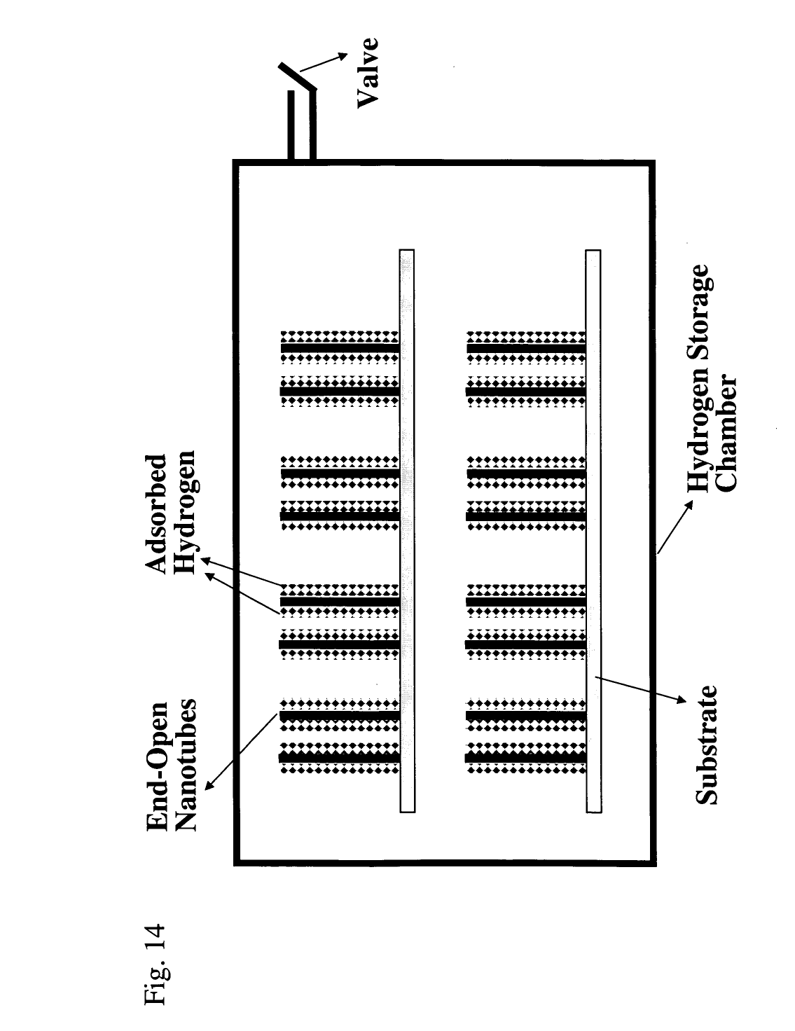

Nanotubes in accordance with example embodiments of the present invention (for example, with enhanced field concentrating capability) may be utilized in a nano-needle delivery device as illustrated, for example, in FIG. 13, or in a higher-capacity hydrogen storage medium and/or associated devices to enable efficient energy creation and/or consumption as illustrated, for example, in FIG. 14.

Examples of such devices and applications involving nanotubes in accordance with example embodiments of the present invention (for example, with enhanced field concentrating capability) are described in greater detail below.

FIG. 9 illustrates a microwave amplifier using nanotubes in accordance with example embodiments of the present invention. Carbon nanotubes are attractive as field emitters because their high aspect ratio (>1,000), one-dimensional structure and/or their relatively small tip radii of curvature approximately 10 nm) tend to effectively concentrate the electric field.

In addition, a beneficial atomic arrangement in a nanotube structure may impart improved mechanical strength and/or chemical stability, both of which make nanotube field emitters robust and stable, especially for higher current applications, such as microwave amplifier tubes.

Microwave vacuum tube devices, such as power amplifiers, may be components of many modern microwave systems, including telecommunications, radar, electronic warfare and navigation systems. While semiconductor microwave amplifiers are available, they generally lack the power capabilities required by most microwave systems.

Microwave vacuum tube amplifiers, in contrast, may provide higher microwave power by orders of magnitude. The higher power levels of vacuum tube devices are the result of the fact that an electron can travel orders of magnitude faster in a vacuum with much less energy loss than the same electron can travel in a solid semiconductor material. Higher electron speed permits the use of a larger structure with the same transit time. A larger structure, in turn, permits a greater power output, which may be required for efficient operations.

Microwave tube devices may operate by introducing a beam of electrons into a region where the beam of electrons may interact with an input signal and derive an output signal from the thus-modulated beam. Microwave tube devices may include gridded tubes, klystrons, traveling wave tubes or crossed-field amplifiers and/or gyrotrons. All may require a source of emitted electrons.

Conventional thermionic emission cathodes, e.g., tungsten cathodes, may be coated with barium or barium oxide, or mixed with thorium oxide, and heated to a temperature of approximately 1000° C. to produce a sufficient thermionic electron emission current on the order of amperes per square centimeter.

The need to heat thermionic cathodes to such high temperatures may cause a number of problems, including limiting the lifetime of the thermionic cathode, introducing warmup delays and/or requiring bulky auxiliary equipment.

Limited lifetime may be a consequence of the higher operating temperature that causes constituents of the cathode, such as barium or barium oxide, to evaporate from the hot surface. When the barium is depleted, the cathode (and hence, the tube) can no longer function. Many thermionic vacuum tubes, for example, have operating lives of less than a year.

Another disadvantage may be the delay in emission from the thermionic cathode due to the time required for temperature ramp-up. Delays up to 4 minutes have been experienced, even after the cathode reaches its desired temperature. This delay length may be unacceptable in fast-warm-up applications, for example, some military sensing and commanding devices.

Yet another disadvantage may be that the high temperature operation requires a peripheral cooling system such as a fan, increasing the overall size of the device or the system in which it is deployed.

Yet another disadvantage may be that the high temperature environment near the grid electrode is such that the thermally induced geometrical/dimensional instability (e.g., due to the thermal expansion mismatch or structural sagging and resultant cathode-grid gap change) does not allow a convenient and direct modulation of signals by the grid voltage alterations.

One or more of these problems and/or other problems may be obviated by a cold cathode and/or a cold-cathode-based electron source for microwave tube devices, for example, which do not require high temperature heating.

A cold cathode type microwave amplifier device according to example embodiments of the present invention may use carbon nanotubes to provide electrons for microwave vacuum tubes at low voltage, low operating temperature and/or with fast-turn-on characteristics.

FIG. 9 illustrates a microwave vacuum tube according to an example embodiment of the present invention. The microwave vacuum tube may include a spaced-apart nanowire cold cathode, which may be of “klystrode” type. The klystrode structure may be of gridded tube type (other types of gridded tubes include triodes and tetrodes). The microwave vacuum tube may further include a cathode 12, a grid 14, an anode 16, a tail pipe 18, and/or a collector 20. The microwave vacuum tube may be optionally placed in a uniform magnetic field for beam control. In operation, a RF voltage may be applied between the cathode 12 and grid 14 by one of several possible circuit arrangements. For example, it is possible for the cathode 12 to be capacitively coupled to the grid 14 or inductively coupled with a coupling loop into an RF cavity containing the grid structure. The grid 14 may regulate the potential profile in the region adjacent the cathode 12, and thereby may control the emission from the cathode 12. The resulting density-modulated (bunched) electron beam 22 may be accelerated toward the anode 16 (for example, an apertured anode) at a high potential.

The electron beam 22 may pass a gap 19, called the output gap, in the resonant RF cavity and/or induce an oscillating voltage and current in the cavity. RF power may be coupled from the cavity by an appropriate technique, such as inserting a coupling loop into the RF field within the cavity. Most of the beam passes through the tail pipe 18 into the collector 20. By depressing the potential of the collector 20, some of the DC beam power can be recovered to enhance the efficiency of the device.

Microwave vacuum tubes according to example embodiments of the present invention and associated klystrode structures, may be more efficient because they may combine one or more of the advantages of resonant circuit technologies of high frequency, velocity-modulated microwave tubes (such as klystrons, traveling wave tubes and crossed-field tubes) and those of the grid-modulation technologies of triodes and tetrodes, together with the cold cathodes using high-current emission capabilities of nanowire field emitters according to example embodiments of the present invention. The cold cathodes according to example embodiments of the present invention may allow the grid to be positioned closer to the cathode, for direct modulation of the electron beam signals with substantially reduced transit time.

Because more efficient electron emission may be achieved by the presence of a gate electrode in close proximity to the cathode (for example, about 1-100 μm distance away), it may be desirable to have a finer-scale, micron-sized gate structure with as many gate apertures as possible to increase emission efficiency and/or reduce the heating effect caused by electrons intercepted by the gate grids.

A grid in a cold cathode type vacuum tube device according to example embodiments of the present invention may be made of conductive metals and may have a perforated, mesh-screen or apertured structure to draw the emitted electrons in, yet let the electrons pass through the apertures and move on to the anode. The apertured grid structure can be prepared by photolithographic or other known patterning technique, as is commercially available. The desired average size of the aperture may be in the range of 0.5-500 μm, or 1-100 μm, or 1-20 μm.

A grid structure according to example embodiments of the present invention may also be in the form of a fine wire mesh screen, for example, with a wire diameter of 5-50 μm and wire-to-wire spacing (or aperture size) of 10-500 μm. The aperture shape may be circular, square or irregular.

Within each aperture area, a multiplicity of nanotube emitters may be attached on the cathode surface which emits electrons when a field is applied between the cathode and the grid. A more positive voltage may be applied to the anode in order to accelerate and impart a relatively high energy to the emitted electrons. The grid may be a conductive element placed between the electron emitting cathode and the anode. The grid may be separated from the cathode but may be kept sufficiently close in order to induce the emission.

The grid may be separated from the cathode either in a suspended configuration or with an electrically insulating spacer layer, for example, an aluminum oxide layer. The dimensional stability of the grid, more particularly, the gap distance between the cathode and the grid, may be important, for example, in the case of unavoidable temperature rise caused by electron bombardment on the grid and resultant change in dimension or geometrical distortion. It may be desirable that the grid be made with a mechanically strong, higher melting point, and/or lower thermal expansion metal, for example, a refractory or transition metal. The use of mechanically strong and/or creep-resistant ceramic materials, for example, higher conductive oxides, nitrides, carbides, may also be an option. The grid may also be configured to have as much mechanical rigidity as possible.

The open-ended nanotube emitters as described in example embodiments of the present invention may also be utilized to make, flat-panel, field emission displays, for example, as illustrated in FIG. 10. Herein, the term “flat panel displays” is arbitrarily defined as meaning “thin displays” with a thickness of e.g., less than approximately 10 cm.

Field emission displays may be constructed with either a diode design (e.g., a cathode-anode configuration) or a triode design (e.g., cathode-grid-anode configuration). The use of a grid electrode may be preferred as the field emission may be more efficient. In an example embodiment, the electrode may be a higher density aperture gate structure placed in proximity to the nanotube emitter cathode to excite emission. A high density gate aperture structure may be obtained e.g., by lithographic patterning.

For display applications, emitter material (the cold cathode) in each pixel of the display may include multiple emitters for the purpose, among others, of averaging out the emission characteristics and ensuring uniformity in display quality. Due to the nanoscopic nature of the nanowires, for example, carbon nanotubes, the emitter may provide multiple emitting points, but due to desired field concentrations, the density of nanotubes in example embodiments may be limited to less than 100/(μm)².

Because more efficient electron emission at lower applied voltage may be improved by the presence of an accelerating gate electrode in proximity (for example, about 1 μm distance), it may be useful to have multiple gate apertures over a given emitter area to more efficiently utilize the capability of multiple emitters. It may also be desirable to have a finer-scale, micron-sized structure with as many gate apertures as possible for improved emission efficiency.

A field emission display according to an example embodiment of the present invention is illustrated in FIG. 10 and may include a substrate 110, which may also act as a conductive cathode, a plurality of spaced-apart and aligned nanotube emitters 112, attached on the conductive substrate 110, and an anode, disposed in a spaced relation from the plurality of emitters 112 within a vacuum seal. A transparent anode conductive layer 116 formed on a transparent insulating substrate 118 (for example, glass) may be provided with a phosphor layer 120 and mounted on support pillars (not shown). Between the cathode 111 and the anode and closely spaced from the plurality of emitters 112 may be a perforated conductive gate layer 122. The gate 122 may be spaced from the cathode 111 by a thin insulating layer 124.

The space between the anode and the plurality of emitters 112 may be sealed and evacuated and voltage may be applied from a power supply 126. The field-emitted electrons from the plurality of emitters 112 may be accelerated by the gate electrode 122, and move toward the anode conductive layer 116 (for example, a transparent conductive layer such as indium-tin-oxide) coated on the anode substrate 118. The phosphor layer 120 may be disposed between the plurality of emitters 112 and the anode. As the accelerated electrons hit the phosphor of the phosphor layer 120, a display image may be generated.

Nano fabrication technologies may be crucial for construction of new nano devices and systems, as well as, for manufacturing of next generation, higher-density semiconductor devices. Conventional e-beam lithography, with single-line writing characteristics, is inherently slow and costly. Projection e-beam lithography technology, which is sometimes called as SCALPEL, may be able to handle approximately 1 cm² type exposure at a time with an exposure time of <1 second.

In a projection electron-beam lithography tool according to an example embodiment of the present invention as illustrated in FIG. 11, a mask may include a lower atomic number membrane covered with a layer of a higher atomic number material, and contrast may be generated by utilizing the difference in electron scattering characteristics between the membrane material and the patterned mask material. The membrane may scatter electrons weakly and to small angles, while the patterned mask layer may scatter electrons strongly and to high angles. An aperture in the back focal plane of the projection optics may block the strongly scattered electrons, forming a high contrast image at the wafer plane to be e-beam patterned, as illustrated in FIG. 11.

In example operation of the projection electron-beam lithography tool, the mask may be uniformly illuminated by a parallel beam of, e.g., 100 keV electrons generated by a cold cathode according to an example embodiment of the present invention further including open-ended nanotube array field emitters according to an example embodiment of the present invention. A reduction-projection optic, produces, for example, a 4:1 demagnified image of the mask at the wafer plane. Magnetic lenses can be used to focus the electrons. Projection e-beam lithography operations based on a 1:1 projection may also be applied.

Open-ended nanotube array structures according to example embodiments of the present invention may also be useful in improving the performance and/or reliability of flat panel plasma displays. Plasma displays utilize emissions from regions of low pressure gas plasma to provide electrodes within visible display elements. A typical display cell may include a pair of sealed cell containing a noble gas. When a sufficient voltage is applied between the electrodes, the gas may ionize, form a plasma, and/or emit visible and/or ultraviolet light. Visible emissions from the plasma can be seen directly. Ultraviolet emissions can be used to excite visible light from phosphors. An addressable array of such display cells may form a plasma display panel. In an example embodiment, display cells may be fabricated in an array defined by two sets of orthogonal electrodes deposited on two respective glass substrates. The region between the substrates may be filled with a noble gas, for example, neon, and sealed.

Plasma displays have found widespread applications ranging in size from small numeric indicators to large graphics displays. Plasma displays % are contenders for future flat panel displays for home entertainment, workstation displays and/or HDTV displays. Using a lower work function material to lower the operating voltage has been described. Open-ended nanotubes according to example embodiments of the present invention may provide improved plasma displays as the more efficient electron emission from the open-ended nanotubes may allows the operation of plasma displays at reduced operating voltages, higher resolution, and/or enhanced robustness.

FIG. 12 illustrates a display cell in accordance with an example embodiment of the present invention. The display cell may include a pair of plates 9 and 10 (for example, glass plates), separated by barrier ribs 11. One plate, for example, plate 9 may include an anode 12 (for example, a transparent anode). The other plate for example, plate 10 may include a cathode 13. The plates 9, 10 may be made of soda lime glass. The anode 12 may be a metal mesh or an indium-tin-oxide (ITO) coating. The cathode 13 may be either metal, for example, Ni, W, stainless steel or a conductive oxide. A noble gas 14, for example, neon, argon or xenon (or mixtures thereof) may fill the space between the electrodes. The barrier ribs 11 may be dielectrics and may separate plates 9, 10 by approximately 200 μm.

In operation, a voltage from a power supply 15 may be applied across the electrodes. When the applied voltage is sufficiently high, a plasma 16 forms and emits visible and/or ultraviolet light. The presence of a nanotube structure 20, in accordance with an example embodiment of the present invention, may allow the plasma 16 to be generated at lower voltages because electron emission from the nanowire under an electrical field or upon collision with ions, metastables and photons are much easier than with conventional materials. This facilitated emission may reduce power consumption, may simplify the driver circuitry, and/or may permit higher resolution.

Referring to FIGS. 13A-13C, an open-ended nanotube array in accordance with an example embodiment of the present invention may also be useful as a basis of a nanoneedle array for delivery of drugs or biomolecules (for example, DNAs, proteins, enzymes, etc.) to the interior of cells for therapeutic and/or diagnostic purposes.

FIGS. 13A-13C illustrate a nanoneedle array in accordance with an example embodiment of the present invention, geometrically fixed on a solid substrate. The nanopores in the open-ended nanotubes may be filled with drugs, molecules, and/or chemicals, for example, by using a supercritical CO₂ deposition technique. As is well known, the supercritical CO₂ has the characteristics of being both vapor-like and liquid-like, and has an ability to dissolve many different types of materials. Supercritical CO₂ can therefore be inserted into even smaller, higher-aspect-ratio nanopores.

FIG. 13B illustrates an open-ended nanotube array filled with a desired type and quantity of drugs, molecules and/or chemicals, which can be utilized for delivery of a minute and prefixed, nanoscale amount of such a material to biological cells as illustrated in FIG. 13C, or for adding a controlled amount of chemical reactants and/or catalysts for lab-on-a-chip type devices, microfluidic devices, etc. As a result, a diffusion-based, slow, and/or well-controlled delivery can be made.

Open-ended nanotube arrays in accordance with an example embodiment of the present invention may also be utilized as the basis for construction of aligned nanocomposites on a substrate, for example, a supercritical CO₂ deposition of ferromagnetic metals or alloys into the core of nanotubes to fill the vertically aligned and open-ended nanotube array for fabrication of ultra-high-density magnetic recording media.

Open-ended nanotube arrays in accordance with an example embodiment of the present invention may also be used as the basis for storing hydrogen gas for fuel. Hydrogen has received much attention in recent years as a clean energy source as its use as a fuel creates neither air pollution nor greenhouse effect emissions. Practical means for H₂ gas storage and transportation have yet been developed. The use of carbon nanotubes may be used to solve the problem of how to efficiently store H₂ gas.

Open-ended nanotube arrays in accordance with an example embodiment of the present invention may allow access to hydrogen atoms inside the nanotube core, thus providing higher capacity of hydrogen storage in carbon nanotubes, as illustrated in FIG. 14. Because hydrogen atoms can be adsorbed onto both the outer wall and inner wall of the nanotubes, Open-ended nanotube arrays in accordance with an example embodiment of the present invention may provide an improvement in hydrogen storage capacity by at least 30% or at least 60% higher than nanotube arrays with a closed-end configuration.

It is understood that the above-described embodiments are illustrative of only a few of the many possible specific embodiments which can represent applications of the invention. Numerous and varied other arrangements can be made by those skilled in the art without departing from the spirit and scope of the invention.

What is claimed is:

1. A method of opening an end of a nanotube including a catalyst particle, comprising:
sputter etching the nanotube to remove an amorphous layer, bend the nanotube to one side, open a hole in the nanotube, and cause detachment of the catalyst particle.

2. The method of claim 1, further comprising:
covering the catalyst particle with an amorphous layer prior to sputter etching.

3. The method of claim 1, wherein detachment of the catalyst particle occurs near a neck of the nanotube.

4. The method of claim 1, wherein the sputter etching occurs at near room-temperature.

5. The method of claim 1, wherein the method does not include wet processing.

6. The method of claim 1, wherein the method does not include high temperature oxidation.

7. The method of claim 1, wherein the sputter etching is carried out using hydrogen ions or argon ions.

8. The method of claim 1, wherein the nanotube is a carbon nanotube in a vertically parallel aligned array configuration.

9. The method of claim 1, wherein the nanotube with a catalyst particle are placed in a gated cell structure.

10. A catalyst-free, open-ended nanotube structure with vertical alignment prepared by the method of claim 1.

11. An article comprising:
an aligned and open-ended nanotube structure which is free of catalyst particles at top ends, the aligned and open-ended nanotube structure having an uneven open-end height with local protruding portions and an average unevenness of at least 2 nm, with a nanotube length after sputter etching of at least 1 nm shorter than the nanotube length before sputter etching.

12. The article of claim 11, wherein the average unevenness is at least 10 nm and the nanotube length after sputter etching is at least 5 nm shorter than the nanotube length before sputter etching.

13. A method of creating an open-ended nanotube array structure comprising:
turning, a solderable or brazeable nanotube array on an original substrate upside down;
bonding the solderable or brazeable nanotube array on a new substrate; and
detaching the original substrate from the bonded assembly to create an open-ended nanotube array structure on the new substrate.

14. The method of claim 13, wherein the new substrate is a conductive substrate.

15. The method of claim 13, wherein the conductive substrate is a semiconductor substrate, doped Si substrate, conductive ceramic substrate, metal substrate, or metal coated substrate.

16. The method of claim 13, wherein the open-ended nanotube array structure is completely metallic-bonded on the new surface.

17. The method of claim 13, further comprising:
cleaning an upper surface of catalyst particles attached on a tip of vertically aligned carbon nanotubes which make up the nanotube array structure before turning the solderable or brazeable nanotube array upside down.

18. The method of claim 17, wherein the upper surface of the catalyst particles are cleaned by plasma etching.

19. The method of claim 17, further comprising:
depositing at least one solderable or brazeable metal or solder alloy on the upper surface of catalyst particles to produce the solderable or brazeable nanotube array after cleaning the upper surface of the catalyst particles.

20. The method of claim 19, wherein the at least one solderable or brazeable metal or solder alloy includes Au, Ag, Cu, Sn, their alloys or solder alloys, including eutectic alloys of Sn—Ag, Au—Sn, Sn—Sb, Sn—Cu, Bi—Sn or Pb—Sn.

21. The method of claim 19, wherein the at least one solderable or brazeable metal or solder alloy is deposited on the top surface of catalyst particles by physical or chemical deposition.

22. The method of claim 21, wherein the physical or chemical deposition includes oblique-incident sputtering or evaporation deposition.

23. The method of claim 19, wherein the at least one solderable or brazeable metal or solder alloy is applied as a thick layer, the thick layer is detached, flipped upside down, and solder bonding onto the new substrate.

24. An article comprising:
a vertically aligned and open-ended nanotube microstructure, free of catalyst particles at top ends thereof and including catalyst metal particles at bottom ends thereof metallically bonded to a substrate with solder or braze.

25. The article of claim 24, wherein the metallic bond is solder or braze selected from Au, Ag, Cu, Sn, their alloys or solder alloys, including eutectic alloys of Sn—Ag, Au—Sn, Sn—Sb, Sn—Cu, Bi—Sn or Pb—Sn.

26. The article of claim 24, wherein the article is a field emitter device.

27. The article of claim 24, wherein the article is a microwave amplifier field emitter device.

28. The article of claim 24, wherein the article is a field emission display devices.

29. The article of claim 24, wherein the article is a field emitter device based electron beam lithography nanofabrication tools.

30. The article of claim 24, wherein the article is a nano-needle array for delivery of drugs, DNA, proteins, or enzymes.

31. The article of claim 24, wherein the article is a nano-needle array for delivery of chemical reactants or catalysts for reactions, lab-on-a-bench devices, or microfluidic devices.

32. The article of claim 24, wherein the article is hydrogen storage devices.

33. The article of claim 24, wherein the article is a fuel cell.
